(19) United States
(12) Patent Application Publication
(10) Pub. No.: US 2015/0002491 A1
(43) Pub. Date: Jan. 1, 2015

(54) DISPLAY DEVICE AND MANUFACTURING METHOD THEREOF

(71) Applicant: SAMSUNG DISPLAY CO., LTD., Yongin-City (KR)

(72) Inventors: Sun-Woo Lee, Yongin-City (KR); Jin-Hee Jeong, Yongin-City (KR)

(21) Appl. No.: 14/317,946

(22) Filed: Jun. 27, 2014

(30) Foreign Application Priority Data
Jul. 1, 2013 (KR) 10-2013-0076640

(51) Int. Cl. G09G 5/00; H05K 3/30

(52) U.S. Cl. CPC G09G 5/00; H05K 3/30
USPC 345/204; 29/846

(57) ABSTRACT

According to an exemplary embodiment of the present invention, the gap between a display panel and a driving circuit is maintained by an insulating side wall that covers the sides of conductors provided on a drive pad and that is higher than the surface of the conductors without adding a photolithography process. Even when, as the resolution of the display device is increased, the gap between two adjacent conductors is reduced, the two adjacent conductors may be prevented from being shorted.

### CROSS-REFERENCE TO RELATED APPLICATION

This application claims priority under 35 U.S.C. §119 to Korean Patent Application No. 10-2013-0076640 filed in the Korean Intellectual Property Office on Jul. 1, 2013, the disclosure of which is incorporated by reference herein in its entirety.

### TECHNICAL FIELD

Exemplary embodiments of the present invention relate to displays, and more specifically, to a display device and a method of manufacturing the same.

### DISCUSSION OF THE RELATED ART

A driving circuit is connected to a display device and transmits signals, such as gate signals and data signals, to the display device. Conductive bumps connect lines of the driving circuit to signal lines of the display device via conductive balls.

When pressure is applied to bring the conductive bumps into contact with the conductive balls, different degrees of load are applied to the center and edge of the conductive bumps, and thus, the gap between the driving circuit and its corresponding substrate varies according to its positions.

As the resolution of the display device is increased, more signal lines are included in the driving circuit, and thus, the gap between two adjacent conductive bumps is reduced. Therefore, the adjacent conductive bumps may be shorted to each other by the conductive balls positioned therebetween.

### SUMMARY

An exemplary embodiment of the present invention provides a display device. The display device includes a display panel including a plurality of pixels. A driving circuit faces the display panel and is combined with the display panel. The driving circuit includes a circuit board. A drive pad is provided on the circuit board. A passivation layer is provided on the drive pad. The passivation layer includes a contact hole for exposing the drive pad. A conductor is provided on the drive pad exposed by the contact hole of the passivation layer. An insulating side wall covers a side of the conductor.

The insulating side wall is higher than a top surface of the conductor.

A top surface of the insulating side wall contacts the display panel.

The display device further includes a conductive ball provided between two opposite portions of the insulating side wall. The conductive ball contacts the conductor and the display panel.

The display panel further includes a pad connected to the pixels, and the drive pad is electrically connected to the pad of the display panel by the conductor and the conductive ball.

An exemplary embodiment of the present invention provides a method for manufacturing a display device. The method includes forming a display panel including a plurality of pixels. A driving circuit for transmitting a driving signal to the display panel is formed. The display panel and the driving circuit are combined with each other. A drive pad is formed on a circuit board. A passivation layer is formed on the drive pad. The passivation layer includes a contact hole for exposing the drive pad. A bump is formed. The bump includes a conductor and an insulating side wall. The conductor is provided on the drive pad exposed by the contact hole of the passivation layer. The insulating side wall covers a side of the conductor.

A conductive layer is formed on the drive pad exposed by the contact hole of the passivation layer. A photosensitive film pattern is formed on the conductive layer. The conductive layer is etched by using the photosensitive film pattern as a mask, forming the conductor. An insulation film covers the photosensitive film pattern and a side of the conductor. The photosensitive film pattern and the insulation film provided on a top surface of the photosensitive film pattern are removed.

The insulating side wall is higher than a top surface of the conductor.

A top surface of the insulating side wall contacts the display panel.

A conductive ball is provided between the insulating side wall. The conductive ball contacts the conductor and the display panel.

A pad connected to the pixels is formed. The drive pad is connected to the pad of the display panel by the conductor and the conductive ball.

According to an exemplary embodiment of the present invention, a display device comprises a display panel and a driving circuit. The display panel has a first pad, and the driving circuit has a second pad. A passivation layer is formed on the second pad. The passivation layer has a contact hole exposing a portion of the second pad. A conductor is formed on the portion of the second pad. A conductive ball is formed between the conductor and the first pad. An insulating side wall is formed on a side of the conductor.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view of a display device according to an exemplary embodiment of the present invention; and

FIG. 2 to FIG. 9 are cross-sectional views of a method for manufacturing a display device according to an exemplary embodiment of the present invention.

### DETAILED DESCRIPTION OF EMBODIMENTS

Hereinafter, exemplary embodiments of the present invention will be described in detail with reference to the accompanying drawings. The invention, however, may be modified in various different ways, and should not be construed as limited to the embodiments set forth herein.

Like reference numerals may denote like or similar elements throughout the specification and the drawings. It will be understood that when an element such as a layer, film, region, or substrate is referred to as being “on,” “coupled to,” or “connected to” another element, it can be directly on, coupled or connected to the other element or intervening elements may also be present.

As used herein, the singular forms “a,” “an,” and “the” are intended to include the plural forms as well, unless the context clearly indicates otherwise.

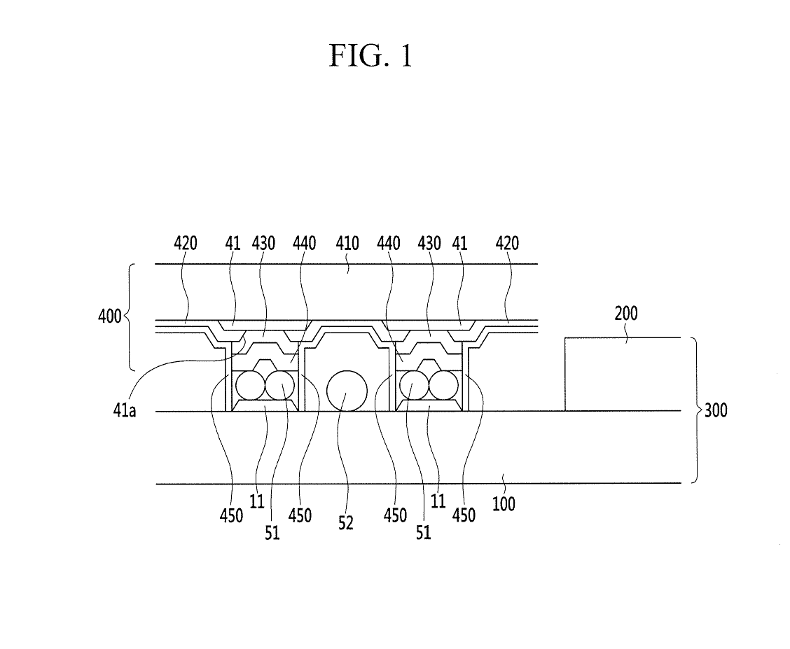

FIG. 1 is a cross-sectional view of a display device according to an exemplary embodiment of the present invention.

Referring to FIG. 1, the display device includes a display panel 300 including a plurality of pixels, a plurality of pads 11 formed on the display panel 300, and a driving circuit 400 connected to the pads 11 of the display panel 300.

The display panel 300 includes a first display panel 100 and a second display panel 200 that are combined with each other.

When the display device is a liquid crystal display (LCD), a gate line, a data line, a switch such as a thin film transistor connected to the gate line and the data line, and a pixel electrode connected to the switch are formed on the first display panel 100, and a common electrode is formed on the second display panel 200. The common electrode can be formed on the first display panel 100. A color filter is formed on the first display panel 100 or the second display panel 200. A liquid crystal layer can be provided between the first display panel 100 and the second display panel 200.

When the display device is an organic light emitting diode (OLED) display, a gate line, a data line, a switch such as a thin film transistor connected to the gate line and the data line, a pixel electrode connected to the switch, a common electrode overlapping the pixel electrode, and an organic light emitter provided between the pixel electrode and the common electrode are formed on the display panel 300.

A plurality of drive pads 41 connected to a driving signal unit are formed on a circuit board 410. The driving signal unit and the drive pads 41 can be formed of a metal having low resistivity such as aluminum or silver.

A passivation layer 420 is formed on the drive pads 41. The passivation layer 420 can include an insulator such as silicon oxide or silicon nitride.

A plurality of contact holes 41a for exposing the drive pads 41 are formed on the passivation layer 420.

A first conductor 430 and a second conductor 440 are formed on the drive pads 41 exposed by the contact holes 41a. Alternatively, the display device may include one conductor or at least three conductors.

The first conductor 430 can include titanium (Ti), and the second conductor 440 can include gold (Au).

Sides of the first conductor 430 and the second conductor 440 are covered by an insulating side wall 450. The insulating side wall 450 can include an insulator such as silicon oxide or silicon nitride.

The insulating side wall 450 is provided on the passivation layer 420 and the sides of the first conductor 430 and the second conductor 440.

The first conductor 430, the second conductor 440, and the insulating side wall 450 configure a bump for a connection between the driving circuit 400 and the display panel 300.

The insulating side wall 450 is higher than the second conductor 440. The height of the bump for a connection between the driving circuit 400 and the display panel 300 is substantially equal to the height of the insulating side wall 450.

The insulating side wall 450 maintains a gap between the first display panel 100 of the corresponding display panel 300 and driving circuit 400. Therefore, a gap between the display panel 300 and the driving circuit 400 is maintained. Accordingly, the gap between the display panel 300 and the driving circuit 400 may be prevented from varying depending on the positions thereof.

The first conductor 430 and the second conductor 440 provided on the drive pads 41 exposed by the contact holes 41a are electrically connected to the pad 11 of the display panel 300 by a first conductive ball 51 provided between two adjacent portions of the insulating side wall 450. A driving signal is transmitted via the first conductive ball 51 to the pad 11 of the display panel 100 from the drive pad 41 of the driving circuit 400.

The sides of the first conductor 430 and the second conductor 440 provided on the drive pad 41 are covered by the insulating side wall 450, and a second conductive ball 52 provided between two adjacent first conductors 430 or between two adjacent second conductors 440 does not contact the first conductor 430 or the second conductor 440. Therefore, although, as the resolution of the display device is increased, the gap between the two adjacent first conductors 430 or two adjacent second conductors 440 is reduced, the two adjacent first conductors 430 or the two adjacent second conductors 440 may be prevented from being shorted.

The display device according to an exemplary embodiment of the present invention includes the insulating side wall 450 that covers the sides of the first conductor 430 and the second conductor 440 provided on the drive pad 41 and that is higher than the surface of the second conductor 440. Thus, the gap between the display panel 300 and the driving circuit 400 may be maintained, and even when, as the resolution of the display device is increased, the gap between two adjacent first conductors 430 or two adjacent second conductors 440 is reduced, the two adjacent first conductors 430 or the two adjacent second conductors 440 may be prevented from being shorted.

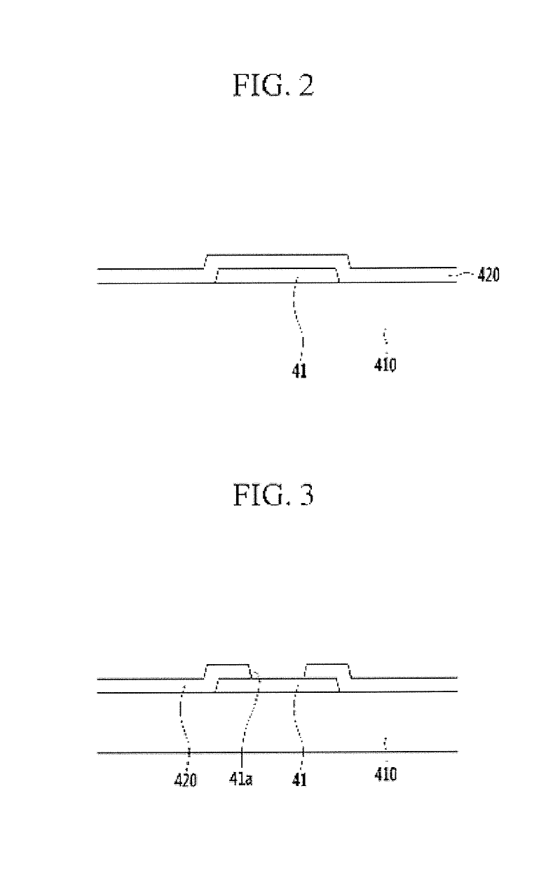

FIG. 2 to FIG. 9 are cross-sectional views of a method for manufacturing a display device according to an exemplary embodiment of the present invention.

Referring to FIG. 2, a plurality of drive pads 41 are formed on a circuit board 410. The drive pads 41 can include a metal having low resistivity such as aluminum or silver.

As shown in FIG. 3, a passivation layer 420 is formed on the drive pads 41, and a contact hole 41a for exposing a part of the drive pad 41 is formed through the passivation layer 420. The passivation layer 420 can be formed of an insulator such as silicon oxide or silicon nitride.

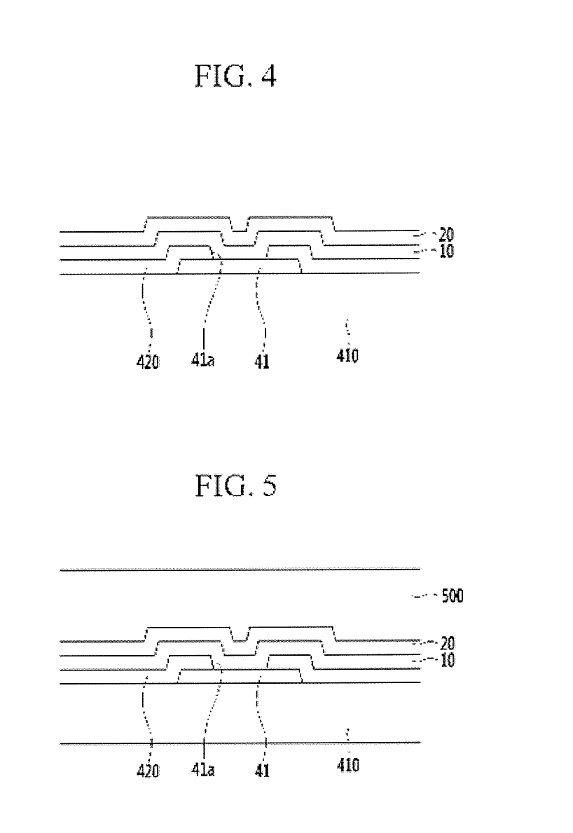

Referring to FIG. 4, a first conductive layer 10 and a second conductive layer 20 are sequentially deposited on the drive pad 41 exposed by the contact hole 41a of the passivation layer 420. The first conductive layer 10 can include titanium (Ti), and the second conductive layer 20 can include gold (Au). The first conductive layer 10 and the second conductive layer 20 are different from each other, according to an exemplary embodiment. However, exemplary embodiments of the present invention are not limited thereto. Alternatively, a single conductive layer or three or more conductive layers may be deposited on the drive pads 41.

Referring to FIG. 5, a photosensitive film 500 is deposited on the second conductive layer 20.

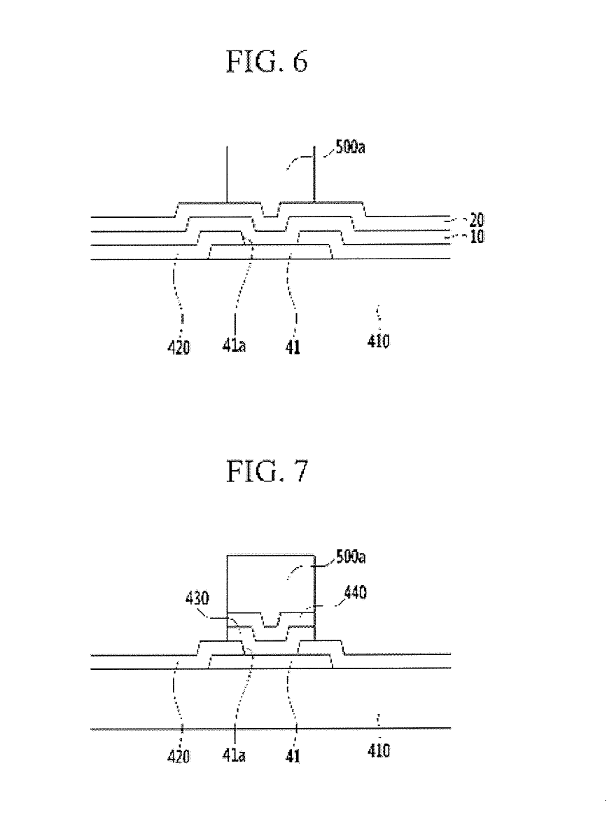

The photosensitive film 500 is exposed and developed, forming a photosensitive film pattern 500a as shown in FIG. 6.

Referring to FIG. 6, the second conductive layer 20 and the first conductive layer 10 are etched by using the photosensitive film pattern 500a as an etching mask, forming a first conductor 430 and a second conductor 440.

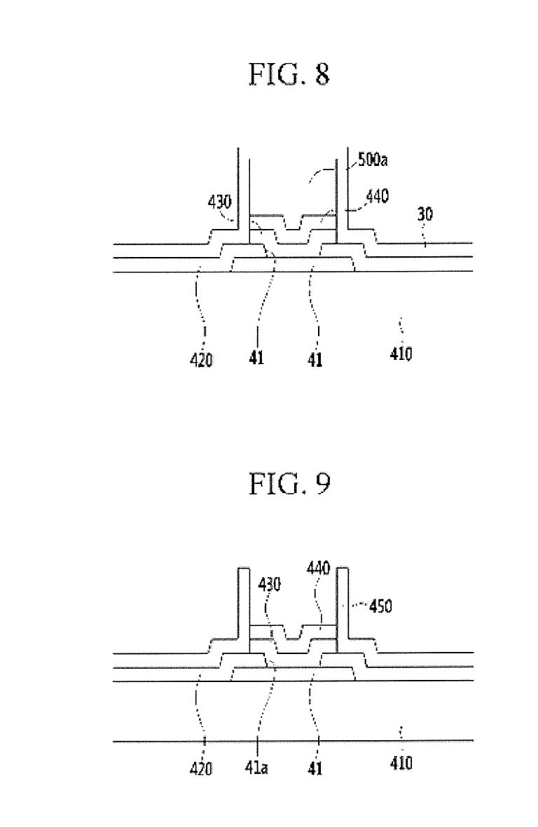

Referring to FIG. 8, an insulation layer 30 covers the photosensitive film pattern 500a and sides of the first conductor 430 and the second conductor 440. The insulation layer 30 can include an insulator such as silicon oxide or silicon nitride.

As shown in FIG. 9, the photosensitive film pattern 500a and an upper portion of the insulation layer 30 provided on the photosensitive film pattern 500a are removed, and the remaining insulation layer 30 becomes an insulating side wall 450.

As shown in FIG. 1, a plurality of conductive balls 51 and 52 are coated on the first display panel 100 of the display panel 300. With the display panel 300 facing the driving circuit 400, a pressure is applied to the display panel 300 and the driving circuit 400, allowing the display panel 300 and the driving circuit 400 to be bonded to each other. The conductive balls 51 and 52 can be spread in an adhesive material layer for attaching the driving circuit 400 and the display panel 300 with each other.

By a method for manufacturing a display device according to an exemplary embodiment of the present invention, the gap between the display panel 300 and the driving circuit 400 is maintained by forming the insulating side wall 450 that covers the sides of the first conductor 430 and the second conductor 440 provided on the drive pad 41 and that is higher than the surface of the second conductor 440 without adding a photolithography process. Even when the resolution of the display device is increased, and thus, the gap between two adjacent first conductors 430 or between two adjacent second conductors 440 is reduced, the two adjacent first conductors 430 or the two adjacent second conductors 440 may be prevented from being shorted.

The display device according to an exemplary embodiment of the present invention is applicable to various types of flat panel displays having a display panel connected to a driving circuit that is positioned outside the display panel, such as a liquid crystal display (LCD) or an organic light emitting diode (OLED) display.

While the invention has been shown and described in connection with exemplary embodiments thereof, it is to be understood by those of ordinary skill in the art that various changes in form and detail may be made thereto without departing from the spirit and scope of the invention as defined by the following claims.

What is claimed is:

1. A display device, comprising:
a display panel including a plurality of pixels; and
a driving circuit facing the display panel, the driving circuit combined with the display panel, wherein the driving circuit comprises:
a circuit board;
a drive pad provided on the circuit board;
a passivation layer provided on the drive pad and including a contact hole exposing the drive pad;
a conductor provided on the drive pad exposed by the contact hole of the passivation layer; and
an insulating side wall covering a side of the conductor.

2. The display device of claim 1, wherein the insulating side wall is higher than a top surface of the conductor.

3. The display device of claim 2, wherein a top surface of the insulating side wall contacts the display panel.

4. The display device of claim 3, further comprising a conductive ball provided between two opposite portions of the insulating side wall, the conductive ball contacting the conductor and the display panel.

5. The display device of claim 4, wherein the display panel further comprises a pad connected to the plurality of pixels, and wherein the drive pad is electrically connected to the pad of the display panel by the conductor and the conductive ball.

6. The display device of claim 1, wherein a top surface of the insulating side wall contacts the display panel.

7. The display device of claim 6, further comprising a conductive ball provided between the insulating side wall, the conductive ball contacting the conductor and the display panel.

8. The display device of claim 7, wherein the display panel further comprises a pad connected to the pixels, and wherein the drive pad is electrically connected to the pad of the display panel by the conductor and the conductive ball.

9. The display device of claim 1, further comprising a conductive ball provided between the insulating side wall, the conductive ball contacting the conductor and the display panel.

10. The display device of claim 9, wherein the display panel further comprises a pad connected to the pixels, and wherein the drive pad is electrically connected to the pad of the display panel by the conductor and the conductive ball.

11. A method for manufacturing a display device, the method comprising:
forming a display panel including a plurality of pixels;
forming a driving circuit, the driving circuit configured to transmit a driving signal to the display panel; and
combining the display panel with the driving circuit, wherein forming the driving circuit comprises:
forming a drive pad on a circuit board;
forming a passivation layer including a contact hole on the drive pad, the contact hole exposing the drive pad; and
forming a bump, the bump including a conductor and an insulating side wall, wherein the conductor is provided on the drive pad exposed by the contact hole of the passivation layer, and wherein the insulating side wall covers a side of the conductor.

12. The method of claim 11, wherein forming the bump comprises:
forming a conductive layer on the drive pad exposed by the contact hole of the passivation layer;
forming a photosensitive film pattern on the conductive layer;
forming the conductor by etching the conductive layer by using the photosensitive film pattern as a mask;
forming an insulation film on the photosensitive film pattern and a side of the conductor; and
removing the photosensitive film pattern and the insulation film provided on a top surface of the photosensitive film pattern.

13. The method of claim 12, wherein the insulating side wall is higher than a top surface of the conductor.

14. The method of claim 13, wherein a top surface of the insulating side wall contacts the display panel.

15. The method of claim 14, wherein a conductive ball is provided between two opposite portions of the insulating side wall, the conductive ball contacting the conductor and the display panel.

16. The method of claim 15, wherein forming the display panel further includes forming a pad connected to the pixels, wherein the drive pad is connected to the pad of the display panel by the conductor and the conductive ball.

17. The method of claim 11, wherein the insulating side wall is higher than a top surface of the conductor.

18. The method of claim 17, wherein the top surface of the insulating side wall contacts the display panel.

19. The method of claim 18, wherein a conductive ball is provided between the insulating side wall, the conductive ball contacting the conductor and the display panel.

20. The method of claim 19, wherein forming the display panel further includes forming a pad connected to the pixels, wherein the drive pad is connected to the pad of the display panel by the conductor and the conductive ball.

21. The method of claim 11, wherein a top surface of the insulating side wall contacts the display panel.

22. The method of claim 21, wherein a conductive ball is provided between the insulating side wall, the conductive ball contacting the conductor and the display panel.

23. The method of claim 22, wherein forming the display panel further includes forming a pad connected to the pixels, wherein the drive pad is connected to the pad of the display panel by the conductor and the conductive ball.

24. The method of claim 11, wherein a conductive ball is provided between the insulating side wall, the conductive ball contacting the conductor and the display panel.

25. The method of claim 24, wherein forming the display panel further includes forming a pad connected to the pixels, wherein the drive pad is connected to the pad of the display panel by the conductor and the conductive ball.
